(19) United States
(12) Patent Application Publication
(10) Pub. No.: US 2011/0315435 A1
(43) Pub. Date: Dec. 29, 2011

(54) ACID ANHYDRIDE CURABLE THERMOSETTING RESIN COMPOSITION

(76) Inventor: Ming Jen TZOU, Taipei County (TW)

(21) Appl. No.: 12/825,052

(22) Filed: Jun. 28, 2010

(51) Int. Cl. H05K 1/09; B32B 15/092; C08L 61/06

(52) U.S. Cl. 174/257; 524/509; 428/418

(57) ABSTRACT

The present invention provides a resin composition suitable for printed circuit boards, the composition includes one epoxy resin or the mixture thereof, curing agent, promoting agents and additives, wherein the ratio of curing agent to epoxy resin is 1.55˜2.5, in which epoxy resin consists of at least one of phenol-formaldehyde multi-functional epoxy resin; curing agent comprises at least one of styrene-maleic anhydride copolymer. After hardening, this resin composition has excellent electrical properties, high glass transition temperature and excellent heat-resistant properties, applicable to the lead-free printed circuit board manufacturing process, and in the field of the high-frequency and packaging-board containing printed circuit boards.

### FIELD OF THE INVENTION

The present invention relates to an epoxy resin composition with high glass transition temperature, superior thermal resistance and excellent electric properties, which is suitable for preparing prepreg, laminates and copper clad laminates (CCL), can be applied to electronic components and printed circuit board (PCB) in the high frequency field, or used as carrier substrate materials for package.

### BACKGROUND OF THE INVENTION

Epoxy resin has been used in copper clad laminates and printed circuit boards for many years, the main reason thereof is that the adhesion strengths between epoxy resin and reinforcing materials such as glass fiber cloths, glass fiber mats and paper etc. are good, no volatile component is emitted during curing, and shrinkage is less during molding; the resulted copper clad laminate possesses superior mechanical strength, electric insulation, chemical resistance, good dimension accuracy and easy to be processed, thus it becomes a most important raw material for printed circuit boards.

At the moment, the copper clad laminate (CCL) used in printed circuit boards is mainly FRP-4 based on not only quantity but also technical level, but the development of the electronics industry is advanced rapidly by leaps and bounds, the important related components—printed circuit boards should also keep up with the pace of time.

As for system products, light, thin, short, small, power saving and durable are the trend, nevertheless the size of the corresponding electronic components becomes smaller at continuously elevated operating frequency, decreased voltage, reduced transistor power consumption and less tolerate voltage noise, thus it is resulted the emerging one by one of the problems which are originally are not necessary to be considered in the low-frequency area; only in terms of printed circuit boards of the interconnection industry, two major development trends has already been generated: firstly the high density printed circuit board: the main technologies are fine circuits, small holes, blind holes, buried holes; secondly high-frequency electronic component carrier substrates and printed circuit boards for high-speed electronics: the main technologies include low dielectric constant, low dissipation factor for board materials and thin medium layer materials and the precision impedance control, etc.

The 21st century will become a video generation, the high-frequency high-speed application is one important trend of development of the future high-speed printed circuit board (PCB), the traditional FR-4 substrate can still meet the most current printed circuit board industry demand, and holds the largest market share; however, with increasing demand in the material properties and cost considerations, the standard FR-4 substrate (epoxy glass cloth board) can meet the demand of generic products, but as for the high frequency transmission products, the substrate materials are requested to have higher qualities, thus the low dielectric constant, low dissipation factor substrate just complies with the information products to meet the requirements of high-speed and high-frequency and coordinates the communication products for the massive and rapid transmission of voice and video data.

The copper clad laminate (CCL) material is mainly formed by a reinforcing material and a resin composition, the outer layer thereof is pasted together with copper foils, so the resin composition will be one of the main factors to impact electric properties of the substrate. The present patent describes the development of the resin composition to achieve the effectiveness of improving electric properties of substrate boards.

In patent BE-627,887, it is mentioned that the copolymer of maleic anhydride and styrene is used as the curing agent of the epoxy resin, but the disadvantages of this epoxy resin composition are low glass transition temperature (Tg) and poor heat resistance so that it is not suitable for the application of copper clad laminates (CCL) and printed circuit boards (PCB) manufacturing.

When anhydride-type curing agent (hardener) is used with the epoxy resin, it will react rapidly at room temperature upon the addition of an accelerator (promoter), thus this is not suitable to be used in the field of printed circuit boards.

The resin system currently used for copper clad laminates and printed circuit boards is epoxy resin, and generally the standard FR4 substrate is used, whose main ingredient is bisphenol A epoxy resin or brominated epoxy resin manufactured from tetrabromobisphenol A wherein the curing agent is dicyanide diamine, besides an accelerator and solvents are added; the disadvantages of the epoxy resin composition are a low glass transition temperature (Tg) (120-140° C.) and poor heat resistance, if the multi-functional epoxy resin is used to replace bisphenol A epoxy resin to elevate crosslinking density and thereby eliminate the disadvantage of the low glass transition temperature (Tg), but it is without much contribution to improve the heat resistance and electrical properties.

U.S. Pat. No. 6,509,414 reveals the use of styrene maleic anhydride copolymer (SMA) as a resin curing agent, which can improve the heat resistance of a general bi-functional epoxy resin; besides, a co-crosslinking agent is used, for example, styrene maleic anhydride copolymer (SMA) is used with co-crosslinking agent, such as tetrabromobisphenol A (TBBA), tetrabromo-bisphenol A diglycidyl ether (TBBADGE), to improve the glass transition temperature (Tg) of sheet materials; wherein the equivalent proportion of acid anhydride, aromatic hydroxy group (OH) to epoxy resin is 50%˜150% in the mixed resin. Revealed by the examples, it is clearly understood that if the equivalent proportion is increased from 70% to 110%, then the DSC glass transition temperature (Tg) is elevated from 122° C. to 155° C., but if the equivalent proportion is further increased from 110% to 150%, the DSC glass transition temperature (Tg) drops to 137° C. from 155° C. This phenomenon is advised that when the equivalent proportion is more than around 110%, the crosslinking agent will no longer be able to enhance the crosslinking density, so that the DSC glass transition temperature (Tg) can not be raised.

Nowadays copper clad laminates (CCL) and printed circuit boards (PCB) manufacturing trends from the halogen system (mainly brominated flame retardant agent TBBA) towards a non-brominated (mainly phosphorus based flame retardant agent) or even a halogen-free system; the modified maleic anhydride copolymer curing agent synthesis of the present invention is in response to the future environmental protection demand, the present system may be a halogen system, a phosphorus system or a halogen-free system.

### DETAILED DESCRIPTION OF THE INVENTION

The present invention provides a price reasonable anhydride curable thermosetting resin composition, suitable for printed circuit boards, this composition includes one epoxy resin or the mixture thereof, curing agents, promoters and additives, wherein the ratio of curing agent to epoxy resin is 1.55˜2.5, in which at least one of epoxy resin consists of phenol-formaldehyde multi-functional epoxy resin (type I); curing agents comprises at least one of styrene-maleic anhydride copolymer. After hardening, this resin composition has excellent electrical properties, high glass transition temperature and excellent heat-resistance, applicable to the lead-free printed circuit board manufacturing process, and in the field of the high-frequency and packaging-board containing printed circuit boards.

### DESCRIPTION OF THE PREFERRED EMBODIMENT

The present invention provides a resin composition which has excellent electrical properties, high glass transition temperature and excellent heat-resistant properties after curing, thus can be applied to the lead-free printed circuit board manufacturing process, and in the area of high-frequency and high-level printed circuit boards. This resin composition includes one epoxy resin or the mixture thereof, curing agents, promoters and additives.

The described epoxy resin mixture is chosen from at least a phenol-benzaldehyde multi-functional epoxy resin (formula I) (U.S. Pat. No. 6,512,075), the purpose of using phenol-formaldehyde multi-functional epoxy resin is that the epoxy resin chemistry of this structure shows a high-density benzene ring structure and an appropriate number of epoxy functional group. So it has excellent heat resistance and high Tg, meanwhile the suitable number of epoxy functional group and the three-dimensional structure hindrance of the benzene ring give an appropriate reactivity, higher resin melt viscosity, so there is a wide processing window for lamination. Mono-functional group or dual-functional epoxy resin, bisphenol A epoxy resin and bisphenol F epoxy resin with epoxy equivalent 150˜3,000 g/eq. are chosen for enhancing the bonding strength and the impregnation. Brominated epoxy resin, phosphorus based epoxy resin, nitrogen based epoxy resin or phenol-benzaldehyde containing brominated multifunctional epoxy resin can be selected for enhancing the flame resistance. In addition, cyanate ester resin, PPO resin, dicyclopentadiene (DCPD) epoxy resin, for example cyanate ester resin BA230, PT60 with cyanate functional groups and so on made by Lonza can incorporated to improve electrical characteristics.

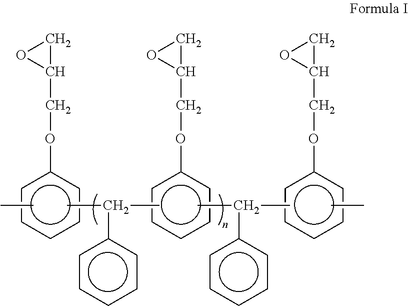

The preparation of above phenol-benzaldehyde multi-functional epoxy resin includes the condensation reaction of phenol and benzaldehyde in the presence of acid catalysts, and then the reaction of the resulted phenol-benzaldehyde with 1-chloro-2,3-epichlorohydrin in the presence of sodium hydroxide to synthesize phenol-benzaldehyde multi-functional epoxy resin. The synthesis reaction conditions are the same as the general epoxidation process with the use of 1-chloro-2,3-epichlorohydrin, the synthesized phenol-benzaldehyde multi-functional epoxy resin shows an epoxy equivalent of 210˜260 g/eq, the average functional group number of 2˜6, and the average molecular weight Mw of 400˜2500. The brominated phenol-benzaldehyde multifunctional epoxy resin includes (A) 10˜70 wt % of phenol-benzaldehyde polyfunctional epoxy resin, (B) 0˜55 wt % of bi-functional epoxy resin with an epoxy equivalent of 170˜500 g/eq, (C) 0˜20 wt % of bromine-containing bi-functional epoxy resin with an epoxy equivalent of 300˜500 g/eq, bromine content of 30˜55%, (D) 15˜40 wt % of tetrabromobisphenol A with a molecular weight of 544, at first, (D) is reacted with at least one epoxy resin selected from (A), (B) or (C) to obtain a brominated epoxy resin, and then the remaining part of (A), (B) or (C) are added and mixed uniformly, the resulted brominated epoxy resin shows an average molecular weight Mw of 1500˜4000, a molecular weight distribution index (Mw/Mn ratio) of 1.5˜4.0, an epoxy equivalent of 300˜500 g/eq.

The choice of the said epoxy resin mixture depends on the processability, physical properties; one or more of the above-mentioned the resin may be used.

The above mentioned curing agent is at least selected from one of styrene-maleic anhydride copolymers, the purpose of selecting acid anhydride curing agent is because the acid anhydride compounds have excellent thermal properties, low moisture absorption, and the addition of anhydride compounds with a styrene structure is because the styrene compounds show excellent electrical characteristics, in addition to enhance the heat-resistance of the resin composition, it can also improve the electrical properties of the resin composition. The acid anhydride curing agent used in the invention is a styrene-maleic anhydride polymer with styrene structure as shown below, selected from one or more marketed SMA1000, SMA2000, SMA3000, EF10, EF20, EF30, EF40, EF80, etc. Anhydride to epoxy equivalent ratio is 1.55˜2.5, preferably 1.55˜2.3, this resin composition after curing has excellent electrical properties, high Tg and excellent heat resistance.

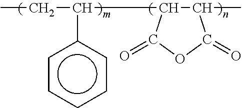

m, n are the same or different positive integers

The purpose of adding accelerant (promoter) is to promote cross-linking reaction between resin and curing agent and the amount added will affect the reaction rate; the promoter is selected from one or more of tertiary amine and its salts, quaternary ammonium salt compounds, imidazoles, mono- or polyphenol compounds, boron trifluoride and its organic compound complex, phosphoric acid or triphenyl phosphite. But the tertiary amine and its salts, imidazoles, or the mixture thereof are preferable.

Additives as described are used in accordance with the characteristic needs of the resin composition and added to achieve to improve or enhance processability, mechanical properties and sheet properties. One or more of inorganic powders, flame retardant agents or toughening agent are chosen. For example, to increase the stiffness or reduce the thermal expansion coefficient of the post-cured resin composition, inorganic powders, such as silica can be charged, while alumina, silicon carbide can be used to improve the thermal conductivity and so on. And high molecular weight phenoxy resin, rubber etc., such as INCHEMREZ PKHS (a high molecular weight phenoxy resin) can be introduced to increase toughness and impact strength of the formulation system; for example, Hycar® CTBN 1300×8 rubber can be incorporated to improve the bonding strength with copper foils. And flame retardant agents, such as tetrabromobisphenol A (TBBA), or PX200 retardant agent supplied by Big Eight Industrial co. can be added to increase the flame retardance of the sheets.

The purpose of this invention is to provide an affordable, anhydride curable thermosetting resin composition, the composition can be at room temperature completely dissolved with solvent into a stable homogeneous varnish, which can be used to manufacture prepreg and copper clad laminates in the application of printed circuit boards.

The described prepreg is prepared as follows: the resin composition of this invention is deployed into a varnish, the reinforced material is impregnated in the epoxy resin varnish, then the solvent therein is evaporated in a heated oven at the same time the resin composition undergoes a partial reaction to become a semi-cured film (B-stage). The reinforcing material can be glass fiber, carbon fiber, Kevlar fiber, paper fiber, such as aromatic polyamide paper, etc.; the prepreg can be further pressed into a copper clad laminate; i.e. one or more of prepreg are combined, and copper foils are placed on both sides, then the composition is pressurized and heated to become a copper clad laminate composite.

The inventive resin composition after hardening shows a high glass transition temperature (Tg), excellent thermal properties and excellent electrical characteristics, can be applied to a general or high-frequency field of printed circuit boards. The present invention is described in more detail by a number of examples, without restricting the invention in any way whatsoever.

### Example 1

100 grams of phenol-benzaldehyde multi-functional epoxy resin (Nan Ya's NPPN-433) and 104 grams of styrene-maleic anhydride copolymer (EF30) are pre-dissolved in methyl ethyl ketone (MEK) to form a 60% solution, and 0.04 grams of the promoter 2MI is added, wherein the equivalent ratio of acid anhydride to epoxy resin is 1.2, based the overall resin solid content.

This resin composition is stirred for 3 hours, followed by testing on 170° C. hot-plate to reveal a gel time of 270 seconds; this solution is poured into a dipping tank, wherein glass fiber cloth (model 7628) is continuously impregnated, and the solvent is evaporated through a heating oven, at the same time the resin composition is carried out a partial reaction to result in a semi-cured film (B-stage), this semi-cured film is taken out of the oven, and cooled to room temperature, then is cut into pieces; 8 thin half-solidified films are piled up, a copper foil (specification 1 oz) is laminated on each side respectively, the resulted laminate is pressed in a hot press with a pressure of 20˜30 kg/cm² and a heating rate 2.5° C./minute to 195° C. for 60 to 120 minutes, thus the resin composition continues the reaction to hardening completion (C-stage) by way of the hot press, and proves to have a glass transition temperature (Tg) of 175° C. and excellent thermal resistance and so on with the physical properties test. The physical properties test data are listed in Table 2.

### Example 2

In the resin composition according to Example 1, the equivalent proportion of acid anhydride to epoxy resin is raised to be 1.75, again following the above manufacturing method, the physical properties of the cured resin composition is tested, the result shows that besides the original characteristics are kept, Tg and electrical properties are improved. The physical properties test data are listed in Table 2.

### Example 3

Following the resin composition according to Example 2, except that 20% of flame retardant PX200, 10% of aluminum hydroxide and 10% of silicon dioxide are added wherein the percentages are based on the overall resin solid content, again in accordance with the above manufacturing method, the physical properties of the cured resin composition is tested, the result shows that besides the original characteristics are kept, the thermal expansion coefficient is lower and flame retardance is improved. The physical properties test data are listed in Table 2.

### Example 4

100 grams of brominated phenol-benzaldehyde multi-function epoxy resin (Nan Ya Corporation NPEB-487A80) is used, 70.9 grams of styrene-maleic anhydride copolymer of (EF30)/methyl ethyl ketone (MEK) solution is added in the above solution to form 60% solution and 0.04 gram of the promoter 2MI is introduced, wherein the equivalent proportion of acid anhydride to epoxy resin is 1.65. According to the manufacturing method of Example 1, the physical properties test proves 188° C. of Tg and superior thermal stability and so on. The physical properties test data are listed in Table 2.

### Example 5

In the resin composition according to Example 4, the equivalent proportion of acid anhydride to the epoxy resin is increased to 2.20, and 18.9 grams of the high molecular weight phenoxy resin (INCHEMREZ PKHS) is incorporated, According to the manufacturing method of Example 1, the physical properties test proves 195° C. of Tg and superior thermal stability and so on. The physical properties test data are listed in Table 2.

### Comparative Example 1

100 gram of brominated epoxy resin as a main resin ingredient which is made from bisphenol A epoxy resin and tetrabromobisphenol A is first pre-dissolved in dimethyl formamide (DMF), and dicyandiamide is used as a curing agent, wherein the equivalence ratio of epoxy resin to curing agent is 0.5 based on the overall resin solid content, then the dose of promoter 2MI is increased, and methyl ethyl alkone (MEK) is added as a solvent to adjust the solid content to be 65%. According to the manufacturing method of Example 1, the physical properties test shows 195° C. of Tg and stable in 288° C. tin stove thermal resistance test for 2˜3 minutes. The physical properties test data are listed in Table 2.

### Comparative Example 2

Based upon Comparative Example 1, but brominated resin of phenol-benzaldehyde multi-function epoxy resin (Nan Ya Corporation NPEB-487A80) is used to replace brominated epoxy resin made from bisphenol A epoxy resin and tetrabromobisphenol A. According to the manufacturing method of Example 1, the physical properties test shows 170° C. of Tg and stable in 288° C. tin stove thermal resistance test for 2˜3 minutes. The physical properties test data are listed in Table 2.

TABLE 1
Resin Composition Equivalence Ratio of Examples and Comparative
Examples

| | | | | | | Comparative | |
|---|---|---|---|---|---|---|---|
| | Examples | | | | | Examples | |
| | 1 | 2 | 3 | 4 | 5 | 1 | 2 |
| Equivalent Ratio | 1.2 | 1.75 | 1.75 | 1.65 | 2.20 | 0.5 | 0.5 |

TABLE 2
Copper Clad Laminate Characteristics of Examples and Comparative
Examples

| | | | | | | Comparative | Comparative |
|---|---|---|---|---|---|---|---|
| | Example 1 | Example 2 | Example 3 | Example 4 | Example 5 | Example 1 | Example 2 |
| Glass Transition | 175 | 189 | 176 | 188 | 195 | 140 | 170 |
| Temperature (DSC), ° C. | | | | | | | |
| Copper Foil | 6.4 | 6 | 6 | 6.5 | 6.2 | 12 | 10 |
| Anti-Tearing Strength, | | | | | | | |
| lb/in | | | | | | | |
| Soldering Tin | >10 | >10 | >10 | >10 | >10 | 2~3 | 2~3 |
| Heat-Resistance Test^{a} | | | | | | | |
| (288° C.), min | | | | | | | |
| Decomposition | 362 | 369 | 361 | 367 | 371 | 310 | 315 |
| Temperature (Td), ° C. | | | | | | | |
| T288 (TMA), min | >30 | >30 | >30 | >30 | >30 | 2~3 | 2~3 |
| CTE, ppm/° C. | — | 50/280 | 45/250 | — | — | — | — |
| Dielectric Constant | 3.91 | 3.8 | 3.79 | 3.82 | 3.76 | 4.6 | 4.3 |
| (1 GHz) | | | | | | | |
| Dissipation Factor | 0.01 | 0.01 | 0.009 | 0.01 | 0.009 | 0.025 | 0.015 |
| (1 GHz) | | | | | | | |

^{a}after pressure cooker for 30 mins

In summary, the resin composition containing phenol-benzaldehyde multi-function epoxy resin and styrene-maleic anhydride curing agent after hardening has high Tg, superior thermal stability and electrical properties. If the equivalent proportion of acid anhydride to epoxy resin is raised, besides Tg is higher, the lowering of dielectric constants and dissipation factors has a distinct improvement; if the equivalent proportion of acid anhydride to the epoxy resin is 1.55˜2.5, most preferably 1.55˜2.3, the resin composition with high Tg, and excellent electrical properties will be obtained, which is suitably used in printed circuit boards.

What is claimed is:

1. An acid anhydride curable thermosetting resin composition, including one epoxy resin or the mixture thereof, curing agents, promoters and additives, wherein the ratio of curing agent to epoxy resin is 1.55˜2.5; the epoxy resin mixture is chosen at least one from phenol-benzaldehyde polyfunctional epoxy resin, and the curing agent is chosen at least one from styrene-maleic anhydride copolymer.

2. The acid anhydride curable thermosetting resin composition according to claim 1, wherein the optimal equivalent ratio of anhydride to epoxy is 1.55 to 2.3.

3. The acid anhydride curable thermosetting resin composition according to claim 1, wherein the epoxy equivalent of phenol-benzaldehyde multi-functional epoxy resin is 210˜260 g/eq, the average functional group number is 2˜6, average molecular weight Mw is 400˜2500.

4. The acid anhydride curable thermosetting resin composition according to claim 1, wherein the composition contains brominated phenol-benzaldehyde multifunctional epoxy resin, wherein the fraction of phenol-benzaldehyde multifunctional epoxy resin is 10˜70%, its epoxy equivalent is 300˜500 g/eq, average molecular weight Mw is 1500˜4000, and molecular weight distribution index is 1.5˜4.0.

5. The acid anhydride curable thermosetting resin composition according to claim 1, in which the promoter can be chosen from one or more of tertial amine and its salts, quaternary ammonium salt compounds, imidazoles, mono- or poly-phenol compounds, boron trifluoride and its complex with organic compounds, phosphoric acid or triphenyl phosphate; preferable is tertiary amine and its salts, imidazoles, or the mixture thereof.

6. The acid anhydride curable thermosetting resin composition according to claim 1, in which depending on the characteristics demand of the resin composition, additives are selected from one or more of inorganic powders, flame retardant agents or toughening agents.

7. The acid anhydride curable thermosetting resin composition according to claim 1, wherein the composition is impregnation, or coating on the reinforcement material to obtain prepreg.

8. The acid anhydride curable thermosetting resin composition according to claim 1, wherein the composition is impregnation, or coating on the reinforcement material to obtain a laminated sheet.

9. A copper clad laminate is obtained with hot pressed the prepreg obtained according to claim 7.

10. A printed circuit board is obtained with hot pressed and wet processed the copper clad laminate obtained according to claim 9.
